(19) United States
(12) Patent Application Publication
(10) Pub. No.: US 2026/0202191 A1
(43) Pub. Date: Jul. 16, 2026

(54) LITHOGRAPHIC APPARATUS AND INSPECTION SYSTEM FOR MEASURING WAFER DEFORMATION

(71) Applicant: ASML NETHERLANDS B.V., Veldhoven (NL)

(72) Inventor: Henricus Petrus Maria PELLEMANS, Veldhoven (NL)

(73) Assignee: ASML NETHERLANDS B.V., Veldhoven (NL)

(21) Appl. No.: 19/135,795

(22) PCT Filed: Nov. 30, 2023
(86) PCT No.: PCT/EP2023/083799

§ 371 Date: Jun. 4, 2025

Related U.S. Application Data
(60) Provisional application No. 63/435,760, filed on Dec. 28, 2022.

(51) Int. Cl. G01B 11/16; G03F 7/00; G03F 9/00

(52) U.S. Cl. CPC G01B 11/161; G03F 7/70783; G03F 9/7049; G03F 9/7065; G03F 9/7076; G03F 9/7088; G03F 9/7092

(57) ABSTRACT

A system for measuring deformation of a substrate includes an illuminator, a camera, a modulator system, and a controller. The illuminator directs two beams of radiation at each target of a plurality of targets disposed on the substrate to produce two beams of scattered radiation from each target. The camera detects interference patterns of the two beams of scattered radiation from the plurality of targets and generates an interferogram based on the interference pattern. The modulator system adjusts the interference patterns by adjusting a relative phase of the two beams of radiation. The controller analyzes the measurement signal to determine the deformation of the substrate based on the interferogram and the adjusting of the relative phase.

### CROSS-REFERENCE TO RELATED APPLICATION

This application claims priority of a U.S. application 63/435,760 which was filed on 28 Dec. 2022 and which is incorporated herein in its entirety by reference.

### FIELD

The present disclosure relates to inspection devices and methods, for example, alignment sensors used for sensing alignment position of wafers in lithographic apparatuses and systems.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which can be a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (photoresist or simply “resist”) provided on the substrate. In general, a single substrate will contain a network of adjacent target portions that are successively patterned. Known lithographic apparatuses include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

During lithographic operation, different processing steps can entail different layers to be sequentially formed on the substrate. Accordingly, it can be necessary to position the substrate relative to prior patterns formed thereon with a high degree of accuracy. Generally, alignment marks are placed on the substrate to be aligned and are located with reference to a second object. A lithographic apparatus can use an alignment apparatus for detecting positions of the alignment marks and for aligning the substrate using the alignment marks to ensure accurate exposure from a mask. Misalignment between the alignment marks at two different layers is measured as overlay error.

In order to monitor the lithographic process, parameters of the patterned substrate are measured. Parameters can include, for example, the overlay error between successive layers formed in or on the patterned substrate and critical linewidth of developed photosensitive resist. This measurement can be performed on a product substrate and/or on a dedicated metrology target. There are various techniques for making measurements of the microscopic structures formed in lithographic processes, including the use of scanning electron microscopes and various specialized tools. A fast and non-invasive form of a specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties. Spectroscopic scatterometers direct a broadband radiation beam onto the substrate and measure the spectrum (intensity as a function of wavelength) of the radiation scattered into a particular narrow angular range. By contrast, angularly resolved scatterometers use a monochromatic radiation beam and measure the intensity of the scattered radiation as a function of angle.

Such optical scatterometers can be used to measure parameters, such as critical dimensions of developed photosensitive resist or overlay error (OV) between two layers formed in or on the patterned substrate. Properties of the substrate can be determined by comparing the properties of an illumination beam before and after the beam has been reflected or scattered by the substrate.

Lithographic processes can disfigure, deform, or otherwise alter a wafer due to physical shock (e.g., high heat, mechanical polishing, or the like).

### SUMMARY

Accordingly, it is desirable to improve wafer fabrication and inspection methods. For example, optical inspection disclosed herein can be used to asses wafer deformation more accurately.

In some aspects, a system for measuring deformation of a substrate can comprise an illuminator, a camera, modulator system, and a controller. The illuminator can direct two beams of radiation at each target of a plurality of targets disposed on the substrate to produce two beams of scattered radiation from the each target. The camera can detect interference patterns of the two beams of scattered radiation from the plurality of targets. The camera can generate a measurement signal comprising a signal representation of an interferogram based on the interference pattern. The modulator system can adjust the interference patterns by adjusting a relative phase of the two beams of radiation. The controller can analyze the measurement signal. The controller can determine the deformation of the substrate based on the interferogram and the adjusting of the relative phase.

In some aspects, a lithographic apparatus can comprise an illumination system, a projection system, and an inspection system. The illumination system can illuminate a pattern of a patterning device. The projection system can project an image of the pattern onto a substrate. The inspection system can measure deformation of a substrate. The inspection system can comprise an illuminator, a camera, modulator system, and a controller. The illuminator can direct two beams of radiation at each target of a plurality of targets disposed on the substrate to produce two beams of scattered radiation from the each target. The camera can detect interference patterns of the two beams of scattered radiation from the plurality of targets. The camera can generate a measurement signal comprising a signal representation of an interferogram based on the interference pattern. The modulator system can adjust the interference patterns by adjusting a relative phase of the two beams of radiation. The controller can analyze the measurement signal. The controller can determine the deformation of the substrate based on the interferogram and the adjusting of the relative phase.

In some aspects, a method comprises the following operations. Directing two beams of radiation at each target of a plurality of targets disposed on a substrate to produce two beams of scattered radiation from the each target. Detecting interference patterns of the two beams of scattered radiation from the plurality of targets using a camera. Generating a measurement signal comprising a signal representation of an interferogram based on the interference patterns detected by the camera. Adjusting the interference patterns by adjusting a relative phase of the two beams of radiation. Analyzing the measurement signal using a controller. Determining a deformation of the substrate based on the interferogram and the adjusting of the relative phase.

Further features of various aspects of the present disclosure are described in detail below with reference to the accompanying drawings. It is noted that the present disclosure is not limited to the specific aspects described herein. Such aspects are presented herein for illustrative purposes only. Additional aspects will be apparent to those skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable those skilled in the relevant art(s) to make and use aspects described herein.

FIG. 1A shows a reflective lithographic apparatus, according to some aspects.

FIG. 1B shows a transmissive lithographic apparatus, according to some aspects.

FIG. 2 shows more details of a reflective lithographic apparatus, according to some aspects.

FIG. 3 shows a lithographic cell, according to some aspects.

FIGS. 4A and 4B show inspection apparatuses, according to some aspects.

FIGS. 5 and 6 show inspection systems, according to some aspects.

FIGS. 7 and 8 show target marks on substrates, according to some aspects.

FIG. 9 shows a flow chart of a method, according to some aspects.

FIG. 10 shows arrangements for illuminating targets, according to some aspects.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

The aspects described herein, and references in the specification to “one aspect,” “an aspect,” “an exemplary aspect,” “an example aspect,” etc., indicate that the aspects described can include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of those skilled in the art to effect such feature, structure, or characteristic in connection with other aspects whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein can likewise be interpreted accordingly.

The terms “about,” “approximately,” or the like can be used herein to indicate the value of a given quantity that can vary based on a particular technology. Based on the particular technology, the terms “about,” “approximately,” or the like can indicate a value of a given quantity that varies within, for example, 10-30% of the value (e.g., ±10%, ±20%, or ±30% of the value).

Aspects of the present disclosure can be implemented in hardware, firmware, software, or any combination thereof. Aspects of the disclosure can also be implemented as instructions stored on a computer-readable medium, which can be read and executed by one or more processors. A machine-readable medium can include any mechanism for storing or transmitting information in a form readable by a machine (e.g., a computing device). For example, a machine-readable medium can include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Furthermore, firmware, software, routines, and/or instructions can be described herein as performing certain actions. However, it should be appreciated that such descriptions are merely for convenience and that such actions result from computing devices, processors, controllers, or other devices executing the firmware, software, routines, instructions, etc. The term “machine-readable medium” can be interchangeable with similar terms, for example, “computer program product,” “computer-readable medium,” “non-transitory computer-readable medium,” or the like. The term “non-transitory” can be used herein to characterize one or more forms of computer readable media except for a transitory, propagating signal.

Before describing such aspects in more detail, however, it is instructive to present an example environment in which aspects of the present disclosure can be implemented.

### Example Lithographic Systems

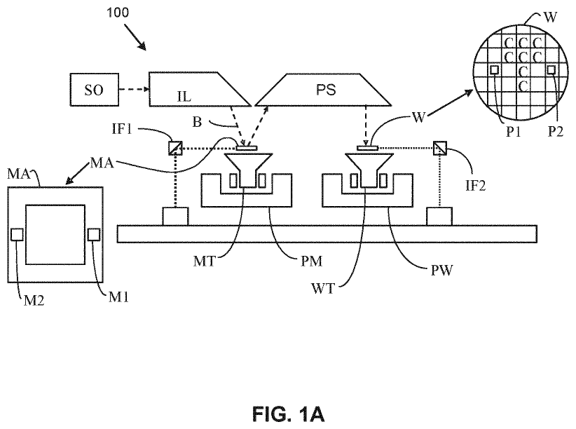

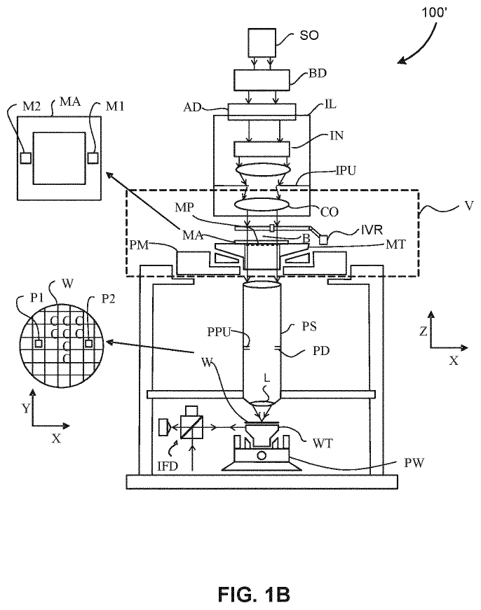

FIGS. 1A and 1B show a lithographic apparatus 100 and a lithographic apparatus 100′, respectively, in which aspects of the present disclosure can be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL can include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

The patterning device MA can be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which can be individually tilted so as to reflect an incoming radiation beam in different directions. The tilted mirrors impart a pattern in the radiation beam B, which is reflected by a matrix of small mirrors.

The term “projection system” PS can encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps.

Lithographic apparatus 100 and/or lithographic apparatus 100′ can be of a type having two (dual stage) or more substrate tables WT (and/or two or more mask tables). In such “multiple stage” machines, the additional substrate tables WT can be used in parallel, or preparatory steps can be carried out on one or more tables while one or more other substrate tables WT are being used for exposure. In some situations, the additional table may not be a substrate table WT.

The lithographic apparatus can also be of a type wherein at least a portion of the substrate can be covered by a liquid having a relatively high refractive index, e.g., water, so as to fill a space between the projection system and the substrate. An immersion liquid can also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid. For example, a liquid can be located between the projection system and the substrate during exposure.

Referring to FIGS. 1A and 1B, the illuminator IL receives a radiation beam from a radiation source SO. The source SO and the lithographic apparatus 100, 100′ can be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO can be an integral part of the lithographic apparatus 100, 100′, for example, when the source SO is a mercury lamp. A radiation system can comprise the source SO, the illuminator IL, and/or the beam delivery system BD.

The illuminator IL can include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illuminator IL can comprise various other components (in FIG. 1B), such as an integrator IN and a condenser CO. The illuminator IL can be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT can be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and substrate W can be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image of the mask pattern MP, where the image is formed by diffracted beams produced from the mark pattern MP by radiation from the intensity distribution, onto a photoresist layer coated on the substrate W. For example, the mask pattern MP can include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture (e.g., using a lens or lens group L) the zeroth order diffracted beams, first order diffracted beams, and/or higher order diffracted beams (not shown). In some aspects, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some aspects, astigmatism aberration can be reduced by providing radiation poles (not shown) in opposite quadrants of the illumination system pupil IPU. Further, in some aspects, astigmatism aberration can be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IFD (for example, an interferometric device, linear encoder, or capacitive sensor), the substrate table WT can be moved accurately (for example, so as to position different target portions C in the path of the radiation beam B). Similarly, the first positioner PM and another position sensor (not shown in FIG. 1B) can be used to accurately position the mask MA with respect to the path of the radiation beam B (for example, after mechanical retrieval from a mask library or during a scan).

In general, movement of the mask table MT can be realized with the aid of a long-stroke module (coarse positioning) and a short-stroke module (fine positioning), which form part of the first positioner PM. Similarly, movement of the substrate table WT can be realized using a long-stroke module and a short-stroke module, which form part of the second positioner PW. In the case of a stepper (as opposed to a scanner), the mask table MT can be connected to a short-stroke actuator or can be fixed. Mask MA and substrate W can be aligned using mask alignment marks M1, M2, and substrate alignment marks P1, P2. Although the substrate alignment marks (as illustrated) occupy dedicated target portions, they can be located in spaces between target portions (known as scribe-lane alignment marks). Similarly, in situations in which more than one die is provided on the mask MA, the mask alignment marks can be located between the dies.

Mask table MT and patterning device MA can be in a vacuum chamber V, where an in-vacuum robot IVR can be used to move patterning devices such as a mask in and out of vacuum chamber. Alternatively, when mask table MT and patterning device MA are outside of the vacuum chamber, an out-of-vacuum robot can be used for various transportation operations, similar to the in-vacuum robot IVR. Both the in-vacuum and out-of-vacuum robots can be calibrated for a smooth transfer of any payload (e.g., mask) to a fixed kinematic mount of a transfer station.

The lithographic apparatus 100 and 100′ can be used in at least one of the following modes:
1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C can be exposed.
2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT can be determined by the (de-) magnification and image reversal characteristics of the projection system PS.
3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO can be employed and the programmable patterning device is updated as needed after each movement of the substrate table WT or in between successive radiation pulses during a scan. This mode of operation can be readily applied to maskless lithography that utilizes a programmable patterning device, such as a programmable mirror array.

Combinations and/or variations on the described modes of use or entirely different modes of use can also be employed.

In some aspects, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

In some aspects, lithographic apparatus 100′ includes a deep ultraviolet (DUV) source, which is configured to generate a beam of DUV radiation for DUV lithography. In general, the DUV source is configured in a radiation system, and a corresponding illumination system is configured to condition the DUV radiation beam of the DUV source.

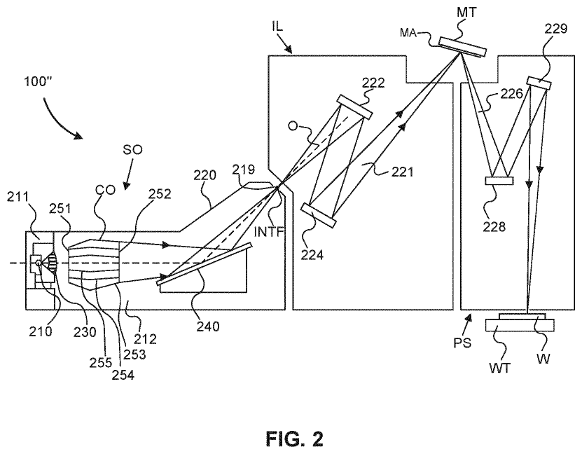

FIG. 2 shows the lithographic apparatus 100 in more detail, including the source collector apparatus SO, the illumination system IL, and the projection system PS. The source collector apparatus SO is constructed and arranged such that a vacuum environment can be maintained in an enclosing structure 220 of the source collector apparatus SO. An EUV radiation emitting plasma 210 can be formed by a discharge produced plasma source. EUV radiation can be produced by a gas or vapor, for example Xe gas, Li vapor, or Sn vapor in which EUV radiation emitting plasma 210 is created to emit radiation in the EUV range of the electromagnetic spectrum. The EUV radiation emitting plasma 210 is created by, for example, an electrical discharge causing at least a partially ionized plasma. Partial pressures of, for example, 10 Pa of Xe, Li, Sn vapor, or any other suitable gas or vapor can be used for efficient generation of the radiation. In some aspects, a plasma of excited tin (Sn) (e.g., excited via a laser) is provided to produce EUV radiation.

The radiation emitted by the EUV radiation emitting plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 can include a channel structure. Contamination trap 230 can also include a gas barrier or a combination of a gas barrier and a channel structure. The contaminant trap or contaminant barrier 230 further indicated herein at least includes a channel structure.

The collector chamber 212 can include a radiation collector CO, which can be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point INTF. The virtual source point INTF is commonly referred to as the intermediate focus, and the source collector apparatus is arranged such that the intermediate focus INTF is located at or near an opening 219 in the enclosing structure 220. The virtual source point INTF is an image of the EUV radiation emitting plasma 210. Grating spectral filter 240 is used in particular for suppressing infra-red (IR) radiation.

Subsequently the radiation traverses the illumination system IL, which can include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown can generally be present in illumination optics unit IL and projection system PS. The grating spectral filter 240 can optionally be present, depending upon the type of lithographic apparatus. Further, there can be more mirrors present than those shown in the FIG. 2, for example there can be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

### Example Lithographic Cell

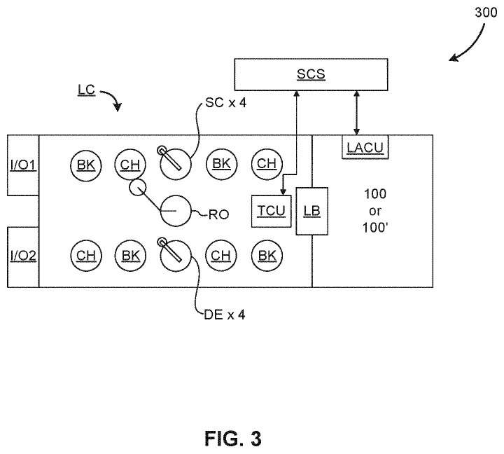

FIG. 3 shows a lithographic cell 300, also sometimes referred to a lithocell or cluster, according to some aspects. Lithographic apparatus 100 or 100′ can form part of lithographic cell 300. Lithographic cell 300 can also include one or more apparatuses to perform pre- and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

### Example Inspection Apparatus

In order to control the lithographic process to place device features accurately on the substrate, alignment marks are generally provided on the substrate, and the lithographic apparatus includes one or more inspection apparatuses for accurate positioning of marks on a substrate. These alignment apparatuses are effectively position measuring apparatuses. Different types of marks and different types of alignment apparatuses and/or systems are known from different times and different manufacturers. A type of system widely used in current lithographic apparatus is based on a self-referencing interferometer as described in U.S. Pat. No. 6,961,116 (den Boef et al.). Generally marks are measured separately to obtain X- and Y-positions. A combined X- and Y-measurement can be performed using the techniques described in U.S. Publication No. 2009/195768 A (Bijnen et al.), however. The full contents of both of these disclosures are incorporated herein by reference.

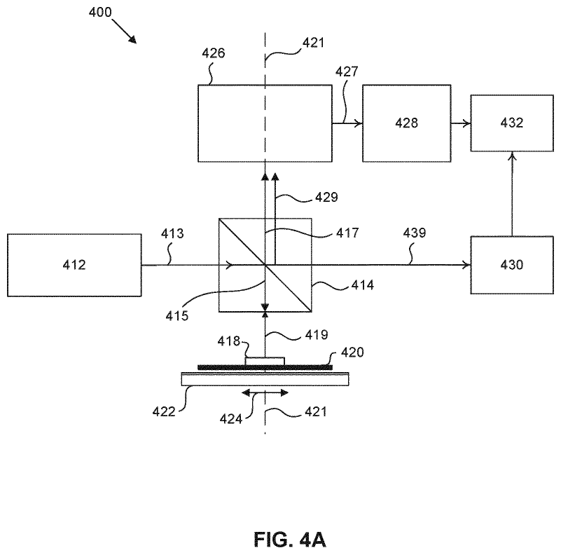

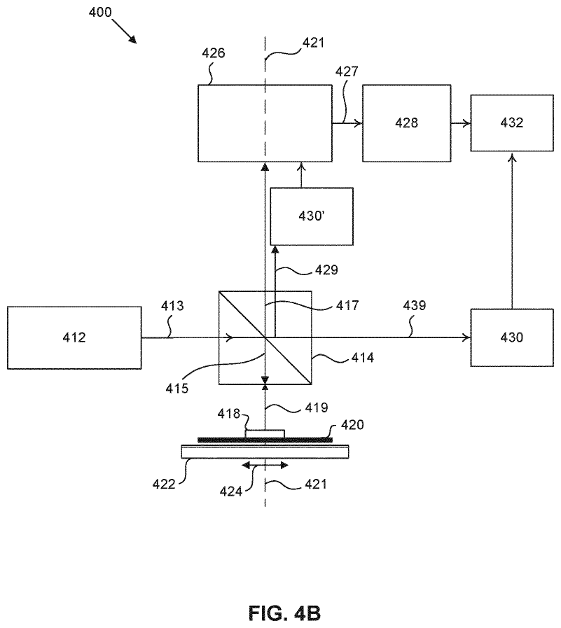

FIG. 4A shows a cross-sectional view of an inspection apparatus 400 that can be implemented as a part of lithographic apparatus 100 or 100′, according to some aspects. In some aspects, inspection apparatus 400 can be configured to align a substrate (e.g., substrate W) with respect to a patterning device (e.g., patterning device MA). Inspection apparatus 400 can be further configured to detect positions of alignment marks on the substrate and to align the substrate with respect to the patterning device or other components of lithographic apparatus 100 or 100′ using the detected positions of the alignment marks. Such alignment of the substrate can ensure accurate exposure of one or more patterns on the substrate.

The terms “inspection apparatus,” “metrology system,” or the like can be used herein to refer to, e.g., a device used for measuring a property of a structure (e.g., overlay sensor, critical dimension sensor, or the like), a device or system used in a lithographic apparatus to inspect an alignment of a wafer (e.g., alignment sensor), or the like.

In some aspects, inspection apparatus 400 can include an illumination system 412, a beam splitter 414, an interferometer 426, a detector 428, a beam analyzer 430, and an overlay calculation processor 432. Illumination system 412 can be configured to provide an electromagnetic narrow band radiation beam 413 having one or more passbands. In an example, the one or more passbands can be within a spectrum of wavelengths between about 500 nm to about 900 nm. In another example, the one or more passbands can be discrete narrow passbands within a spectrum of wavelengths between about 500 nm to about 900 nm. Illumination system 412 can be further configured to provide one or more passbands having substantially constant center wavelength (CWL) values over a long period of time (e.g., over a lifetime of illumination system 412). Such configuration of illumination system 412 can help to prevent the shift of the actual CWL values from the desired CWL values, as discussed above, in current alignment systems. And, as a result, the use of constant CWL values can improve long-term stability and accuracy of alignment systems (e.g., inspection apparatus 400) compared to the current alignment apparatuses.

In some aspects, beam splitter 414 can be configured to receive radiation beam 413 and split radiation beam 413 into at least two radiation sub-beams. For example, radiation beam 413 can be split into radiation sub-beams 415 and 417, as shown in FIG. 4A. Beam splitter 414 can be further configured to direct radiation sub-beam 415 onto a substrate 420 placed on a stage 422. In one example, the stage 422 is movable along direction 424. Radiation sub-beam 415 can be configured to illuminate an alignment mark or a target 418 located on substrate 420. Alignment mark or target 418 can be coated with a radiation sensitive film. In some aspects, alignment mark or target 418 can have one hundred and eighty degrees (i.e., 180°) symmetry. That is, when alignment mark or target 418 is rotated 180° about an axis of symmetry perpendicular to a plane of alignment mark or target 418, rotated alignment mark or target 418 can be substantially identical to an unrotated alignment mark or target 418. The target 418 on substrate 420 can be (a) a resist layer grating comprising bars that are formed of solid resist lines, or (b) a product layer grating, or (c) a composite grating stack in an overlay target structure comprising a resist grating overlaid or interleaved on a product layer grating. The bars can alternatively be etched into the substrate. This pattern is sensitive to chromatic aberrations in the lithographic projection apparatus, particularly the projection system PL, and illumination symmetry and the presence of such aberrations will manifest themselves in a variation in the printed grating. One in-line method used in device manufacturing for measurements of line width, pitch, and critical dimension makes use of a technique known as “scatterometry”. Methods of scatterometry are described in Raymond et al., “Multiparameter Grating Metrology Using Optical Scatterometry”, J. Vac. Sci. Tech. B, Vol. 15, no. 2, pp. 361-368 (1997) and Niu et al., “Specular Spectroscopic Scatterometry in DUV Lithography”, SPIE, Vol. 3677 (1999), which are both incorporated by reference herein in their entireties. In scatterometry, light is reflected by periodic structures in the target, and the resulting reflection spectrum at a given angle is detected. The structure giving rise to the reflection spectrum is reconstructed, e.g. using Rigorous Coupled-Wave Analysis (RCWA) or by comparison to a library of patterns derived by simulation. Accordingly, the scatterometry data of the printed gratings is used to reconstruct the gratings. The parameters of the grating, such as line widths and shapes, can be input to the reconstruction process, performed by processing unit PU, from knowledge of the printing step and/or other scatterometry processes.

In some aspects, beam splitter 414 can be further configured to receive diffraction radiation beam 419 and split diffraction radiation beam 419 into at least two radiation sub-beams, according to an aspect. Diffraction radiation beam 419 can be split into diffraction radiation sub-beams 429 and 439, as shown in FIG. 4A.

It should be noted that even though beam splitter 414 is shown to direct radiation sub-beam 415 towards alignment mark or target 418 and to direct diffracted radiation sub-beam 429 towards interferometer 426, the disclosure is not so limiting. Other optical arrangements can be used to obtain the similar result of illuminating alignment mark or target 418 on substrate 420 and detecting an image of alignment mark or target 418.

As illustrated in FIG. 4A, interferometer 426 can be configured to receive radiation sub-beam 417 and diffracted radiation sub-beam 429 through beam splitter 414. In an example aspect, diffracted radiation sub-beam 429 can be at least a portion of radiation sub-beam 415 that can be reflected from alignment mark or target 418. In an example of this aspect, interferometer 426 comprises any appropriate set of optical-elements, for example, a combination of prisms that can be configured to form two images of alignment mark or target 418 based on the received diffracted radiation sub-beam 429. It should be appreciated that a good quality image need not be formed. It can be enough to have the features of alignment mark 418 resolved. Interferometer 426 can be further configured to rotate one of the two images with respect to the other of the two images 180° and recombine the rotated and unrotated images interferometrically.

In some aspects, detector 428 can be configured to receive the recombined image via interferometer signal 427 and detect interference as a result of the recombined image when alignment axis 421 of inspection apparatus 400 passes through a center of symmetry (not shown) of alignment mark or target 418. Such interference can be due to alignment mark or target 418 being 180° symmetrical, and the recombined image interfering constructively or destructively, according to an example aspect. Based on the detected interference, detector 428 can be further configured to determine a position of the center of symmetry of alignment mark or target 418 and consequently, detect a position of substrate 420. According to an example, alignment axis 421 can be aligned with an optical beam perpendicular to substrate 420 and passing through a center of image rotation interferometer 426. Detector 428 can be further configured to estimate the positions of alignment mark or target 418 by implementing sensor characteristics and interacting with wafer mark process variations.

In a further aspect, detector 428 determines the position of the center of symmetry of alignment mark or target 418 by performing one or more of the following measurements:
1. measuring position variations for various wavelengths (position shift between colors);
2. measuring position variations for various orders (position shift between diffraction orders); and
3. measuring position variations for various polarizations (position shift between polarizations).

This data can be obtained using any type of alignment sensor, for example, a SMASH (SMart Alignment Sensor Hybrid) sensor, as described in U.S. Pat. No. 6,961,116 that employs a self-referencing interferometer with a single detector and four different wavelengths, and extracts the alignment signal in software, or Athena (Advanced Technology using High order ENhancement of Alignment), as described in U.S. Pat. No. 6,297,876, which directs each of seven diffraction orders to a dedicated detector, which are both incorporated by reference herein in their entireties.

In some aspects, beam analyzer 430 can be configured to receive and determine an optical state of diffracted radiation sub-beam 439. The optical state can be a measure of beam wavelength, polarization, or beam profile. Beam analyzer 430 can be further configured to determine a position of stage 422 and correlate the position of stage 422 with the position of the center of symmetry of alignment mark or target 418. As such, the position of alignment mark or target 418 and, consequently, the position of substrate 420 can be accurately known with reference to stage 422. Alternatively, beam analyzer 430 can be configured to determine a position of inspection apparatus 400 or any other reference element such that the center of symmetry of alignment mark or target 418 can be known with reference to inspection apparatus 400 or any other reference element. Beam analyzer 430 can be a point or an imaging polarimeter with some form of wavelength-band selectivity. In some aspects, beam analyzer 430 can be directly integrated into inspection apparatus 400, or connected via fiber optics of several types: polarization preserving single mode, multimode, or imaging, according to other aspects.

In some aspects, beam analyzer 430 can be further configured to determine the overlay data between two patterns on substrate 420. One of these patterns can be a reference pattern on a reference layer. The other pattern can be an exposed pattern on an exposed layer. The reference layer can be an etched layer already present on substrate 420. The reference layer can be generated by a reference pattern exposed on the substrate by lithographic apparatus 100 and/or 100′. The exposed layer can be a resist layer exposed adjacent to the reference layer. The exposed layer can be generated by an exposure pattern exposed on substrate 420 by lithographic apparatus 100 or 100′. The exposed pattern on substrate 420 can correspond to a movement of substrate 420 by stage 422. In some aspects, the measured overlay data can also indicate an offset between the reference pattern and the exposure pattern. The measured overlay data can be used as calibration data to calibrate the exposure pattern exposed by lithographic apparatus 100 or 100′, such that after the calibration, the offset between the exposed layer and the reference layer can be minimized.

In some aspects, beam analyzer 430 can be further configured to determine a model of the product stack profile of substrate 420, and can be configured to measure overlay, critical dimension, and focus of target 418 in a single measurement. The product stack profile contains information on the stacked product such as alignment mark, target 418, or substrate 420, and can include mark process variation-induced optical signature metrology that is a function of illumination variation. The product stack profile can also include product grating profile, mark stack profile, and mark asymmetry information. An example of beam analyzer 430 is Yieldstar™, manufactured by ASML, Veldhoven, The Netherlands, as described in U.S. Pat. No. 8,706,442, which is incorporated by reference herein in its entirety. Beam analyzer 430 can be further configured to process information related to a particular property of an exposed pattern in that layer. For example, beam analyzer 430 can process an overlay parameter (an indication of the positioning accuracy of the layer with respect to a previous layer on the substrate or the positioning accuracy of the first layer with respective to marks on the substrate), a focus parameter, and/or a critical dimension parameter (e.g., line width and its variations) of the depicted image in the layer. Other parameters are image parameters relating to the quality of the depicted image of the exposed pattern.

In some aspects, an array of detectors (not shown) can be connected to beam analyzer 430, and allows the possibility of accurate stack profile detection as discussed below. For example, detector 428 can be an array of detectors. For the detector array, a number of options are possible: a bundle of multimode fibers, discrete pin detectors per channel, or CCD or CMOS (linear) arrays. The use of a bundle of multimode fibers enables any dissipating elements to be remotely located for stability reasons. Discrete PIN detectors offer a large dynamic range but each need separate pre-amps. The number of elements is therefore limited. CCD linear arrays offer many elements that can be read-out at high speed and are especially of interest if phase-stepping detection is used.

In some aspects, a second beam analyzer 430′ can be configured to receive and determine an optical state of diffracted radiation sub-beam 429, as shown in FIG. 4B. The optical state can be a measure of beam wavelength, polarization, or beam profile. Second beam analyzer 430′ can be identical to beam analyzer 430. Alternatively, second beam analyzer 430′ can be configured to perform one or more of the functions of beam analyzer 430, such as determining a position of stage 422 and correlating the position of stage 422 with the position of the center of symmetry of alignment mark or target 418. As such, the position of alignment mark or target 418 and, consequently, the position of substrate 420, can be accurately known with reference to stage 422. Second beam analyzer 430′ can also be configured to determine a position of inspection apparatus 400, or any other reference element, such that the center of symmetry of alignment mark or target 418 can be known with reference to inspection apparatus 400, or any other reference element. Second beam analyzer 430′ can be further configured to determine the overlay data between two patterns and a model of the product stack profile of substrate 420. Second beam analyzer 430′ can also be configured to measure overlay, critical dimension, and focus of target 418 in a single measurement.

In some aspects, second beam analyzer 430′ can be directly integrated into inspection apparatus 400, or it can be connected via fiber optics of several types: polarization preserving single mode, multimode, or imaging, according to other aspects. Alternatively, second beam analyzer 430′ and beam analyzer 430 can be combined to form a single analyzer (not shown) configured to receive and determine the optical states of both diffracted radiation sub-beams 429 and 439.

In some aspects, processor 432 receives information from detector 428 and beam analyzer 430. For example, processor 432 can be an overlay calculation processor. The information can comprise a model of the product stack profile constructed by beam analyzer 430. Alternatively, processor 432 can construct a model of the product mark profile using the received information about the product mark. In either case, processor 432 constructs a model of the stacked product and overlay mark profile using or incorporating a model of the product mark profile. The stack model is then used to determine the overlay offset and minimizes the spectral effect on the overlay offset measurement. Processor 432 can create a basic correction algorithm based on the information received from detector 428 and beam analyzer 430, including but not limited to the optical state of the illumination beam, the alignment signals, associated position estimates, and the optical state in the pupil, image, and additional planes. The pupil plane is the plane in which the radial position of radiation defines the angle of incidence and the angular position defines the azimuth angle of the radiation. Processor 432 can utilize the basic correction algorithm to characterize the inspection apparatus 400 with reference to wafer marks and/or alignment marks 418.

In some aspects, processor 432 can be further configured to determine printed pattern position offset error with respect to the sensor estimate for each mark based on the information received from detector 428 and beam analyzer 430. The information includes but is not limited to the product stack profile, measurements of overlay, critical dimension, and focus of each alignment marks or target 418 on substrate 420. Processor 432 can utilize a clustering algorithm to group the marks into sets of similar constant offset error, and create an alignment error offset correction table based on the information. The clustering algorithm can be based on overlay measurement, the position estimates, and additional optical stack process information associated with each set of offset errors. The overlay is calculated for a number of different marks, for example, overlay targets having a positive and a negative bias around a programmed overlay offset. The target that measures the smallest overlay is taken as reference (as it is measured with the best accuracy). From this measured small overlay, and the known programmed overlay of its corresponding target, the overlay error can be deduced. Table 1 illustrates how this can be performed. The smallest measured overlay in the example shown is −1 nm. However this is in relation to a target with a programmed overlay of −30 nm. The process may have introduced an overlay error of 29 nm.

TABLE 1

| | | | | | | | |
|---|---|---|---|---|---|---|---|
| Programmed overlay | −70 | −50 | −30 | −10 | 10 | 30 | 50 |
| Measured overlay | −38 | −19 | −1 | 21 | 43 | 66 | 90 |
| Difference between | 32 | 31 | 29 | 31 | 33 | 36 | 40 |
| measured and | | | | | | | |
| programmed overlay | | | | | | | |
| Overlay error | 3 | 2 | — | 2 | 4 | 7 | 11 |

The smallest value can be taken to be the reference point and, relative to this, the offset can be calculated between measured overlay and that expected due to the programmed overlay. This offset determines the overlay error for each mark or the sets of marks with similar offsets. Therefore, in the Table 1 example, the smallest measured overlay was −1 nm, at the target position with programmed overlay of 30 nm. The difference between the expected and measured overlay at the other targets is compared to this reference. A table such as Table 1 can also be obtained from marks and target 418 under different illumination settings, the illumination setting, which results in the smallest overlay error, and its corresponding calibration factor, can be determined and selected. Following this, processor 432 can group marks into sets of similar overlay error. The criteria for grouping marks can be adjusted based on different process controls, for example, different error tolerances for different processes.

In some aspects, processor 432 can confirm that all or most members of the group have similar offset errors, and apply an individual offset correction from the clustering algorithm to each mark, based on its additional optical stack metrology. Processor 432 can determine corrections for each mark and feed the corrections back to lithographic apparatus 100 or 100′ for correcting errors in the overlay, for example, by feeding corrections into the inspection apparatus 400.

### Example Local Wafer Deformation Measurements

To appreciate the devices and methods disclosed herein for measuring local wafer deformations, it is instructive to first consider some capabilities and limitations of single cell alignment sensors (single pixel) and camera-based alignment sensors (multiple pixel). In some aspects, as a spot of radiation is moved/scanned across target 418 (FIGS. 4A, 4B), beams of radiation corresponding to opposing diffraction orders (e.g., −1 and +1 orders) can be generated and combined with optical hardware. The combined diffraction orders can be interfered (the above-mentioned SMASH sensor is an example of such a self-referencing sensor and can be implemented according to aspects described herein). Phases of radiation the diffraction orders can evolve over time due to the scanning. As a result of the scanning motion, the measurement signal from detector 428 can have AC modulation characteristics. That is, the measurement signal generated by detector 428 can be an AC signal. A property of target 418 (FIGS. 4A, 4B) (e.g., an alignment position) can be inferred from the characteristics of the AC signal (e.g., from the phase of the AC signal). Any suitable detector can be used for this function, but it is to be appreciated that even a single pixel detector can suffice (e.g., a single-cell photodiode). If a setup is constructed with just one sensor or one detector, then multiple marks can be measured sequentially.

In some aspects, however, sequential measurement of marks can introduce positional uncertainties when moving from mark to mark. For example, a substrate can be supported on a moveable stage. A plurality of alignment marks can be disposed on the substrate. The stage position can be measured by a stage position measurement tool when the stage is moved. The stage position measurement tool can have an uncertainty (tolerance budget). The uncertainty can cause an alignment measurement of an alignment mark to be less accurate.

In some aspects, a camera-based alignment sensor can perform an optical measurement on a large portion of a substrate so as to include a plurality of alignment marks simultaneously in a single measurement, as opposed to a mark-to-mark measurement. This method can mitigate uncertainties associated with stage position measurements. The camera can cover an area large enough to image a portion of a field, an entire field, or multiple fields. Examples of camera-based alignment sensors can be found in U.S. Pat. No. 11,360,399 B2, issued Jun. 14, 2022, which is incorporated by reference herein in its entirety

In some aspects, the terms “field”, “grid”, “die”, “target portion” or the like can be used to describe an iterated portion of a substrate. For example, in FIGS. 1A and 1B, wafer W can have a plurality of target portions C that are repeated (e.g., tessellated). Alignment targets P1 and/or P2 can also be printed on wafer W. While not shown, it is to be appreciated that alignment target(s) can be present within target portions C and/or in between target portions C (e.g., along so-called scribe lanes that designate the borders of fields). A camera-based alignment sensor can image multiple alignment targets within target portion(s) C and/or scribe lanes.

In some aspects, relative positions between alignment targets can be known ahead of time (e.g., predetermined by a specific layout or user-design). When alignment targets are transferred to a substrate, if the substrate is deformed or changes shape (e.g., expands, contracts, warps), a change in the relative positions of alignment targets can be measured in order to quantify the severity of substrate deformation.

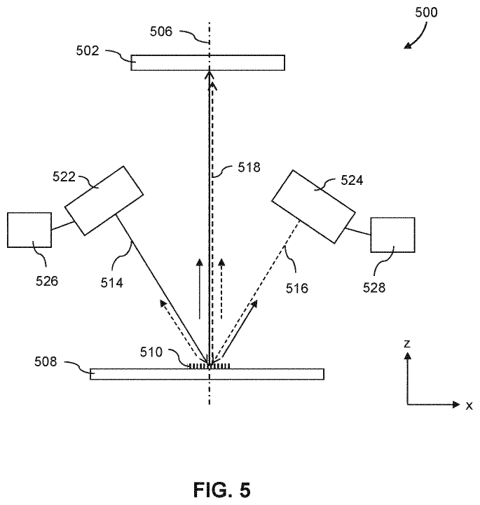

FIG. 5 shows a portion of an inspection system 500, according to some aspects. In some aspects, inspection system 500 can be a camera-based system comprising a camera 502 and an illumination system (e.g., illumination system 412 (FIG. 4A or 4B). The illumination system can comprise portions 522 and 524 and modulators 526 and 528. An optical axis 506 can be defined for inspection system 500 (e.g., a line of sight of inspection system), which can be perpendicular to a surface of a substrate 508 and/or perpendicular to a plane defined by a pixel array of camera 502 (along the z-direction; coordinate system axes are provided by way of non-limiting example). Modulators 526 and 528 can be part of a modulator system.

In some aspects, directions represented by optical axis 506 can be described using terms such as “on-axis” or the like. For example, illumination that propagates in the z-direction can be described as on-axis illumination. Conversely, directions that point at a non-zero angle with respect to optical axis 506 can be described using terms such as “off-axis” (e.g., off-axis illumination).

In some aspects, inspection system 500 can illuminate a target 510 disposed on substrate 508. Target 510 can be illuminated using two beams of radiation 514 and 516 (e.g., first and second beams of radiation). Portions of 522 and 524 of the illumination system can generate beams of radiation 514 and 516 as shown. Beams of radiation 514 and 516 can be off-axis beams that are incident on target 510. A directional component of beam of radiation 514 can be along the +x direction. A directional component of beam of radiation 516 can be along the −x direction. In this manner, beam of radiation 516 can be directed or slanted opposite to beam of radiation 514.

In some aspects, enumerative adjectives (e.g., “first,” “second,” “third,” or the like) can be used to distinguishing like elements without establishing an order, hierarchy, quantity, or permanent numeric definition (unless otherwise noted). For example, the terms “first target” and “second target” can be used in a manner analogous to “i^{th} target” and “j^{th} target” so as to facilitate the distinguishing of two targets without specifying a particular order, hierarchy, quantity, or immutable numeric correspondence.

In some aspects, target 510 can scatter beams of radiation 514 and 516 (represented as scattered illumination 518). To assist in visual disambiguation, solid lines correspond to radiation associated with beam of radiation 514 while dashed lines correspond to beam of radiation 516. Target 510 can be designed to have diffractive properties (e.g., a grating). Target 510 can scatter beam of radiation 514 along directions associated with diffraction orders. The 0^{th} orders shown in FIG. 5 can correspond to directions associated with specular reflection.

In some aspects, valuable information about target 510 can be obtained when analyzing the scatter directions at non-zero diffraction orders. The directions for non-zero order illustrated in FIG. 5 can be, for example, 1^{st} order, 2^{nd} order, 3^{rd} order, or the like. Without limitation, and merely for simplicity, the description will refer to 1^{st} order diffraction. However, those skilled in the art will appreciate that the devices and methods disclosed herein can be implemented using any suitable diffraction order. The coincidence (e.g., overlap of beam spots) of beams of radiation 514 and 516 can produce an interference pattern at target 510. Beams of radiation 514 and 516 can comprise coherent radiation (e.g., from a laser).

In some aspects, by leveraging the incidence angles of beams of radiation 514 and 516 along with characteristic(s) of target 510 (e.g., grating pitch), the 1^{st} order diffraction of beams of radiation 514 and 516 can be made to coincide (e.g., 1^{st} orders can be directed along optical axis 506). The coinciding of the 1^{st} orders is illustrated as scattered illumination 518. Scattered illumination 518 can be received at camera 502. The 1^{st} order diffractions can be interfered at the face of camera 502, forming an interference pattern that can be imaged by camera 502. The interference pattern can be modulated (e.g., moved or shifted) in a number of suitable ways. For example, modulators 526 and 528 can be phase modulators and can modulate phases of one or both of beams of radiation 514 and 516, which can result in the interference pattern at camera 502 to evolve over time. It is to be appreciated that a relative phase of beams of radiation 514 and 516 is modulated. Modulators 526 and/or 528 can comprise phase steppers. In another example, substrate 508 can be moved in order to achieve a similar effect. In another example, the source radiation can be modulated while moving substrate 508.

In some aspects, camera 502 can generate a measurement signal that comprises data that corresponds to scattered illumination 518 and its characteristics (e.g., per-pixel intensity, interference pattern, modulation, phase, or the like). A signal analyzer or controller (e.g., a processor) can be used to analyze the measurement signal in order to inference a property of target 510 (e.g., a position of target 510 relative to a coordinate system of inspection system 500).

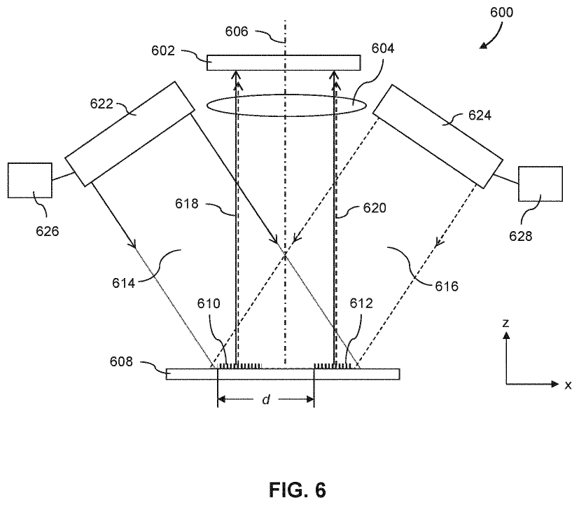

FIG. 6 shows a portion of an inspection system 600, according to some aspects. In some aspects, inspection system 600 can represent a different view of inspection 500 (FIG. 5) to emphasize additional details. Therefore, unless otherwise noted, descriptions of elements of FIG. 5 can also apply to corresponding elements of FIG. 6 and such elements will not be rigorously reintroduced (e.g., reference numbers sharing the two right-most numeric digits). Examples of such elements in FIG. 6 can include camera 602, optical axis 606, substrate 608, target 610, beams of radiation 614 and 616, scattered illumination 618, portions 622 and 624, and modulators 626 and 628. Portions of 622 and 624 can be part of a full-field coherent illuminator.

In some aspects, inspection system 600 can comprise a camera 602 and, optionally, an optical objective 604. In some aspects, inspection system 600 can be used to perform optical measurements of a plurality of targets disposed on substrate 608. As examples, targets 610 and 612 are shown (e.g., first and second targets). Inspection system 600 can illuminate targets 610 and 612 using at least two beams of radiation 614 and 616. Beams of radiation 614 and 616 can represent wide beams that can span two or more targets. Alternatively, beam of radiation 614 can represent a group of beams that can be directed to specific targets (a similar description applies to beam of radiation 616).

In some aspects, when a group of beams are used, each beam can be modulated in a unique manner in order to impart a signature to specific marks. For example, a beam incident on target 610 can have a phase offset φ₁ while a beam incident on target 612 can have a different phase offset φ₂. The different phase offsets can be used by a signal analyzer or controller to identify which pixels of camera 602 receive radiation from either target 610 or 612 (or from other targets using phase offset φₙ)

In some aspects, targets 610 and 612 can scatter beams of radiation 614 and 616. The radiation scattered by target 610 can be represented by scattered illumination 618. The radiation scattered by target 612 can be represented by scattered illumination 620. Optical objective 604 can comprises one or more lenses, one or more mirrors, or the like. Optical objective 604 can optimize scattered illumination 618 and 620 (e.g., focus, collimate, or the like). Camera 602 can receive scattered illumination 618 and 620.

In some aspects, the 1^{st} order diffractions coming from targets 610 and 612 can be interfered at the face of camera 602, forming interference patterns that can be imaged by camera 602. The interference patterns can be modulated (e.g., moved, shifted, adjusted, or the like) as explained in reference to FIG. 5.

In some aspects, camera 602 can generate a measurement signal that comprises data that corresponds to scattered illumination 618 and 620 and their characteristics (e.g., per-pixel intensity, interference pattern, modulation, phase, or the like). A signal analyzer or controller (e.g., a processor) can be used to analyze the measurement signal in order to determine one or more properties of targets 610 and 612 (e.g., positions of targets 610 and 612 relative to a coordinate system of inspection system 600). Targets 610 and 612 can have a predetermined arrangement (illustrated by a distance d in FIG. 6). As substrate 608 experiences undesirable deformations, the measured positional relationship between targets will deviate from the predetermined arrangement. In this manner, deformations of substrate 608 can be quantified.

In some aspects, the image detected by camera 602 can be an interferogram. An interferogram can be, for example, a photographic record made by an apparatus for recording optical interference phenomena. However, it should be understood that a photographic record can be represented in other non-image forms (e.g., in digital data form, analog data signals, or the like). The measurement signal generated by camera 602 can comprise data that is representative of the interferogram(s) on a per-pixel basis. Camera 602 can detect a plurality of interferograms over time. As beams of radiation 614 and/or 616 are modulated (and/or substrate stage is moved), camera 602 can detect a time-evolution of the interferogram. The measurement signal can comprise information about the time-evolution of the interferogram. The interferograms and the time-evolution of the interferograms can be analyzed by the signal analyzer or controller in order to determine one or more properties of targets 610 and 612.

In some aspects, camera 602 can be a high resolution camera. For example, there are chip cameras available for smartphones that have a resolution on the order of 50 megapixels (MP). The state-of-the-art can include cameras capable of resolutions greater than 100 MP. It is envisaged that present and future state-of-the-art cameras can be implemented according to aspects described herein. In some aspects, camera 602 can have a resolution of at least 100 MP, at least 150 MP, at least 200 MP, at least 400 MP, or the like.

In some aspects, camera 602 can also be a high speed camera (fast sampling rate). Speed of measurement can improve the speed at which fabrication can proceed, thereby increasing the number of substrates that can be printed per hour or per day. In some aspects, camera 602 can operate at greater than 500 Hz, 1 kHz, greater than 2 kHz, greater than 5 kHz, greater than 10 kHz, greater than 50 kHz, greater than 100 kHz, greater than 500 kHz, greater than 1 MHz, greater than 2 MHz, or the like.

In some aspects, the numerical aperture (NA) of inspection system 600 (e.g., as defined by optical objective 604) can be less than 0.5, less than 0.4, less than 0.3, less than 0.2, or less than 0.1. In some aspects, a low NA, such as 0.2, can improve accuracy and performance of inspection system 600. Relatively low NA (e.g., less than 0.5) can simplify and ease the process of designing and manufacturing lenses. Some desirable features can include lower complexity of the lens, lower number of optical elements, smaller build volume, lower cost, and the like. In contrast, a full-field, high-NA, multicolor lens can be extremely challenging to manufacture.

In some aspects, since targets can be spread out and distant relative to one another, the processor that is used for analyzing the measurement signal, or a different processor, can also isolate regions of interest on substrate 608 such that only regions that contain a target are analyzed, thereby reducing computational burden that would result from analyzing regions of substrate 608 that are not helpful to the determination of substrate deformation. Examples of region-of-interest (ROI) selection can be found in U.S. Pat. No. 11,360,399 B2.

In some aspects, the quantification of substrate deformation can be achieved by using inspection system 600 to inspect a portion of a field, a full field, multiple fields, or the entirety of substrate 608.

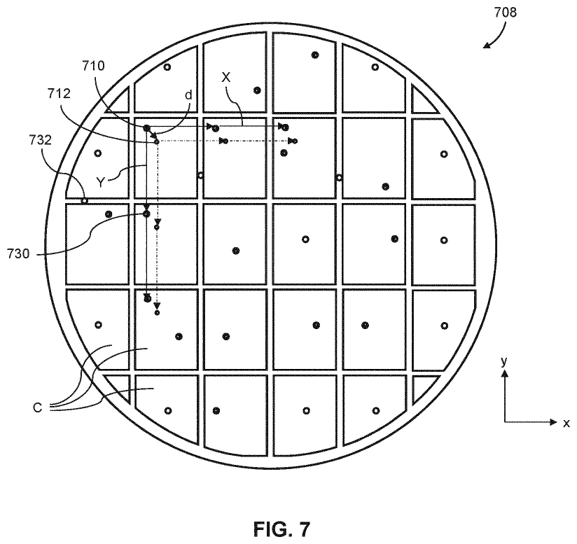

FIG. 7 shows a substrate 708, according to some aspects. In some aspects, substrate 708 can represent a different view of substrates 508 and 608 (FIGS. 5 and 6) to emphasize additional details. Therefore, unless otherwise noted, descriptions of elements of FIGS. 5 and 6 can also apply to corresponding elements of FIG. 7 and such elements will not be rigorously reintroduced (e.g., reference numbers sharing the two right-most numeric digits). Examples of such elements in FIG. 7 can include targets 710 and 712, as well as distance label d. Coordinate system axes x and y are provided by way of non-limiting example.

In some aspects, substrate 708 can comprise fields C (e.g., also called target portions C in FIGS. 1A and 1B) a plurality of targets, and device structures (not shown). Of the plurality of targets, targets 710 and 712 can be intra-field targets, target 730 can be an inter-field target (with respect to targets 710 and 712), and target 732 can be a target in a scribe lane (in between fields C). By using inspection system 600 (FIG. 6) to inspect two or more targets on substrate 708, the measurement can be insensitive to translation effects. That is, a shift or vibration of the whole substrate 708 has the same effect on all targets, which is not a problem for inspection system 600 (as opposed to the very susceptible method of measuring targets sequentially while moving the substrate). This can also allow for pure correlation measurements (target to target correlation), which reduces a requirement for high accuracy on any individual target. Substrate imperfections due to lithographic process effects can also be ignored by the inspection system. First order process effects can be disregarded and inaccuracies can be reduced to second order process effects (e.g., difference in process impact for different marks, field-dependent aberrations, or the like).

In some aspects, a pre-fabrication design choice can be made such that the intra-field targets 710 and 712 are separated by a distance d. As substrate 708 undergoes one or more lithographic processes, substrate 708 can experience deformations, which can cause the relative positions of the targets on substrate 708 to change. For example, while d can be designed so as to be d=L, it can be that it has changed to d=L+ε (where ε is an error value) due to deformations of substrate 708 via the one or more lithographic processes. Similarly, inter-field target distances X and Y can be affected by deformation, which can be quantified using inspection system 600.

In some aspects, the signal analyzer or controller (or another controller) can use the deformation information to adjust a lithographic process, thereby increasing printing accuracy as printed layers are being overlayed one another. For example, the signal analyzer or controller (or another controller) can compensate for the deformation by adjusting a positioning of the substrate stage or by adjusting lens optics in the projection system PS (FIG. 1A or 1B). In another example, the signal analyzer or controller (or another controller) can compensate for the deformation by modifying a physical characteristic or alignment of the patterning device MA (FIG. 1A or 1B). The adjusting of lithographic processes can be performed before an exposure operation for pattern transfer (e.g., perform pre-expose deformation measurements and then perform adjustment of exposure parameters).

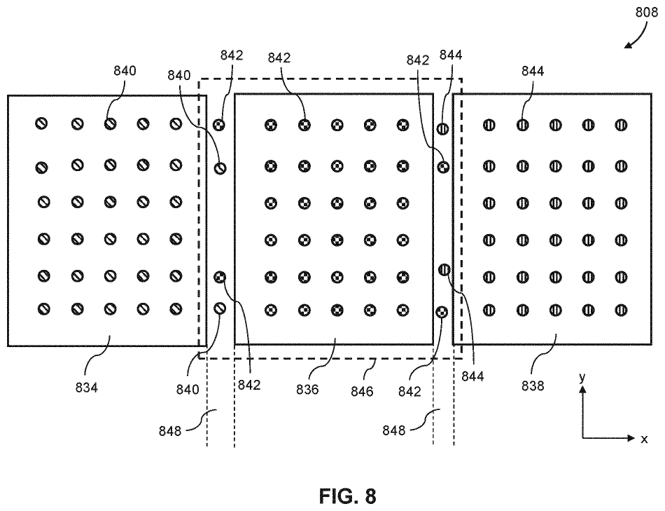

FIG. 8 shows an arrangement of fields and targets on substrate 808, according to some aspects. In some aspects, substrate 808 can represent a different view of substrates 508, 608, and 708 (FIGS. 5-7) to emphasize additional details. Therefore, unless otherwise noted, descriptions of FIGS. 5-7 can also apply to FIG. 8.

In some aspects, substrate 808 can comprise fields 834, 836, and 838 and a plurality of types. Targets 840 (diagonal lines cross hatch) can represent targets associated with field 834. Targets 842 (checker cross hatch) can represent targets associated with field 836. Targets 844 (vertical line cross hatch) can represent targets associated with field 838. Coordinate system axes x and y are provided by way of non-limiting example.

In some aspects, inspection system 600 (FIG. 6) can inspect an area of substrate 808 designated by area 846 (dashed box). Area 846 can encompass the entirety of field 836 and targets disposed therein (e.g., full-field measurement). Area 846 can also encompass one or more scribe lanes 848 and targets disposed therein. Optically inspecting area 846 using inspection system 600 (FIG. 6) makes use of dedicated edge-of-field targets (in combination with to intra-field targets) to measure relative displacement at field edges. Substrate deformation can be characterized by the measured relative displacements.

In some aspects, the illuminator used for illuminating area 846 can be a full-field illuminator (e.g., coherent illuminator). The full-field illuminator can illuminate a full field (e.g., field 836 entirely) plus scribe lanes without needing to move substrate 800.

Referring back to FIG. 6, in some aspects, optical objective 604 (FIG. 6) can comprise a full-field imaging lens. The full-field imaging lens can be configured to operate on-axis (e.g., in the path of optical axis 606). The full-field imaging lens can have a numerical aperture of less than 0.2.

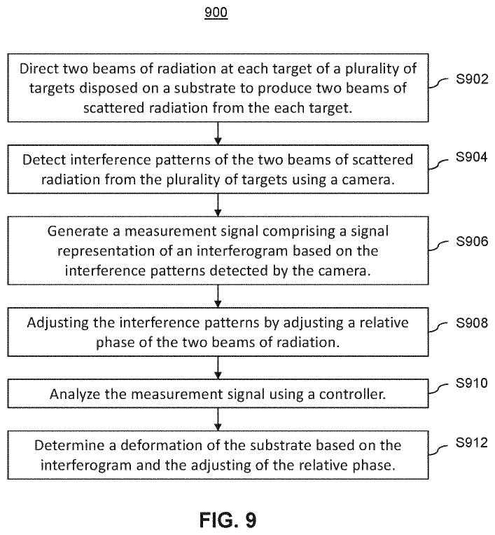

FIG. 9 shows a method 900 for measuring deformation of a substrate, according to some aspects. In some aspects, at step S902, Two beams of radiation can be directed at each target of a plurality of targets disposed on a substrate to produce two beams of scattered radiation from the each target. At step S904, interference patterns are detected using the camera. The interference patterns are of the two beams of scattered radiation from the plurality of targets. At step S906, a measurement signal is generated based on the interference patterns detected by the camera. The measurement signal can comprise a signal representation of an interferogram based on the interference patterns. At step S908, the interference patterns can be adjusted by adjusting a relative phase of the two beams of radiation. At step S910, the measurement signal can be analyzed using a controller. At step S912, a deformation of the substrate can be determined based on the interferogram and the adjusting of the relative phase (that is, the adjusting of the interference patterns).

The method steps of FIG. 9 can be performed in any conceivable order and it is not required that all steps be performed. Moreover, the method steps of FIG. 9 described above merely reflect an example of steps and are not limiting. That is, further method steps and functions are envisaged based aspects described in reference to FIGS. 1-8.

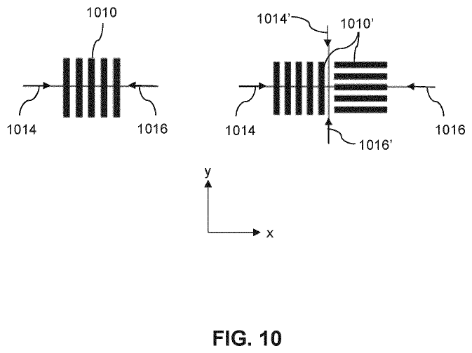

FIG. 10 shows arrangements for illuminating targets 1010 and 1010′, according to some aspects. In some aspects, targets 1010 and 1010′ can represent a different view of targets 510, 610, and/or 612 (FIGS. 5 and 6) to emphasize additional details. Therefore, unless otherwise noted, descriptions of elements of FIGS. 5 and 6 can also apply to corresponding elements of FIG. 10 and such elements will not be rigorously reintroduced (e.g., reference numbers sharing the two right-most numeric digits). Examples of such elements in FIG. 10 can include beams of radiation 1014 and 1016. Coordinate system axes x and y are provided by way of non-limiting example.

In some aspects, beams of radiation 1014 and 1016 can be diametrically opposite about optical axis 506 (FIG. 5). Such a configuration can work for target 1010, which is shown as comprising a one-dimensional grating structure (e.g., grating pitch is along a single direction). However, in some aspects, target 1010′ can comprise more complex structures (e.g., two-dimensional structures, two-dimensional gratings, a set of perpendicular gratings, or the like). That is, target 1010′ can comprise first periodic structures having a first pitch along a first direction (e.g., x direction) and second periodic structures having a second pitch along a second direction (e.g., y direction) that is different from the first direction. In order to inspect both structures of target 1010′ in a single measurement event, additional beams of radiation can be implemented.

That is, in some aspects, two or more pairs of beams of radiation (e.g., two additional beams of radiation 1014′ and 1016′) can be used, which can produce additional beams of scattered radiation (in addition to scattered radiation 618 and 620 (FIG. 6)) from target 1010′. Beams of radiation 1014′ and 1016′ can be arranged diametrically opposite about optical axis 506 (FIG. 5). Beams of radiation 1014′ and 1016′ can propagate along a direction that is perpendicular to a propagation direction beams of radiation 1014 and 1016. Camera 602 (FIG. 6) can detect interference patterns of the two additional beams of scattered radiation. The measurement signal generated by camera 602 can, therefore, also comprise a signal representation of an additional interferogram based on the interference patterns of the two additional beams of scattered radiation. The determining of the deformation performed by the analyzer (e.g., processor 432 (FIG. 4)) can be further based on the additional interferogram.

The embodiments may further be described using the following clauses:

1. A system configured to measure deformation of a substrate, comprising:
an illuminator configured to direct two beams of radiation at each target of a plurality of targets disposed on the substrate to produce two beams of scattered radiation from the each target;
a camera configured to detect interference patterns of the two beams of scattered radiation from the plurality of targets and to generate a measurement signal comprising a signal representation of an interferogram based on the interference patterns;
a modulator system configured to adjust the interference patterns by adjusting a relative phase of the two beams of radiation; and
a controller configured to analyze the measurement signal and to determine the deformation of the substrate based on the interferogram and the adjusting of the relative phase.

2. The system of clause 1, wherein the modulator system comprises a phase stepper configured to adjust the interference patterns by modulating a phase of at least one of the two beams of radiation.

3. The system of clause 1, wherein the substrate is positioned by a substrate table that is configured to move the substrate to adjust the interference patterns detected by the camera.

4. The system of clause 1, wherein the illuminator comprises a full-field phase coherent illuminator.

5. The system of clause 4, wherein:
the substrate comprises:
   a grid of fields; and
   a scribe lane at an edge of a field;
the plurality of targets are distributed among the field and the scribe lane disposed at the edge of the field; and
the full-field phase coherent illuminator is configured to illuminate all targets in the field and the scribe lane disposed at the edge of the field without moving the substrate.

6. The system of clause 1, wherein the camera has a resolution of at least 100 megapixels.

7. The system of clause 1, wherein the camera has a resolution of at least 150 megapixels.

8. The system of clause 1, further comprising an optical objective having a numerical aperture less than 0.5.

9. The system of clause 1, wherein the optical objective comprises a full-field imaging lens having a numerical aperture of less than 0.2.

10. The system of clause 1, wherein the camera is further configured to capture images at a rate of at least 500 Hz, at least 1 kHz, at least 5 kHz, at least 10 kHz, or at least 100 kHz.

11. The system of clause 1, wherein the controller is further configured to, or another controller is configured to, compensate for the deformation by adjusting a positioning of a stage or a projection system of a lithographic apparatus.

12. The system of clause 1, wherein the controller is further configured to, or another controller is configured to, modify a physical characteristic of a patterning device or an alignment of the patterning device of a lithographic apparatus.

13. The system of clause 1, wherein:
the illuminator is further configured to direct two additional beams of radiation at the each target of the plurality of targets to produce two additional beams of scattered radiation, wherein the each target comprises a first periodic structures having a first pitch along a first direction and second periodic structures having a second pitch along a second direction that is different from the first direction;
the camera is configured to detect interference patterns of the two additional beams of scattered radiation;
the measurement signal further comprises a signal representation of an additional interferogram based on the interference patterns of the two additional beams of scattered radiation; and
the determining of the deformation is further based on the additional interferogram.

14. A lithographic apparatus comprising:
an illumination system configured to illuminate a pattern of a patterning device;
a projection system configured to project an image of the pattern onto a substrate; and
an inspection system configured to measure deformation of the substrate, the inspection system comprising:
   an illuminator configured to direct two beams of radiation at each target of a plurality of targets disposed on the substrate to produce two beams of scattered radiation from the each target;
   a camera configured to detect interference patterns of the two beams of scattered radiation from the plurality of targets and to generate a measurement signal comprising a signal representation of an interferogram based on the interference patterns;
   a modulator system configured to adjust the interference patterns by adjusting a relative phase of the two beams of radiation; and
   a controller configured to analyze the measurement signal and to determine the deformation of the substrate based on the interferogram and the adjusting of the relative phase.

15. The lithographic apparatus of clause 14, wherein the modulator system comprises a phase stepper configured to adjust the interference patterns by modulating a phase of at least one of the two beams of radiation.

16. The lithographic apparatus of clause 14, wherein the substrate is positioned by a substrate table that is configured to move the substrate to adjust the interference patterns detected by the camera.

17. The lithographic apparatus of clause 14, wherein the illuminator comprises a full-field phase coherent illuminator.

18. The lithographic apparatus of clause 17, wherein the full-field phase coherent illuminator is configured to illuminate a full field and scribe lanes disposed on the substrate without moving the substrate.

19. The lithographic apparatus of clause 14, wherein the camera has a resolution of at least 100 megapixels.

20. The lithographic apparatus of clause 14, wherein the camera has a resolution of at least 150 megapixels.

21. The lithographic apparatus of clause 14, further comprising an optical objective having a numerical aperture below 0.5.

22. The lithographic apparatus of clause 21, wherein the optical objective comprises a full-field imaging lens having a numerical aperture of less than 0.2.

23. The lithographic apparatus of clause 14, wherein the camera is further configured to capture images at a rate of at least 500 Hz, at least 1 kHz, at least 5 kHz, at least 10 kHz, or at least 100 kHz.

24. The lithographic apparatus of clause 14, wherein the controller is further configured to, or another controller is configured to, compensate for the deformation by adjusting a positioning of a stage or the projection system.

25. The lithographic apparatus of clause 14, wherein the controller is further configured to, or another controller is configured to, modify a physical characteristic of the patterning device or an alignment of the patterning device.

26. The lithographic apparatus of clause 14, wherein:
the illuminator is further configured to direct two additional beams of radiation at the each target of the plurality of targets to produce two additional beams of scattered radiation, wherein the each target comprises a first periodic structures having a first pitch along a first direction and second periodic structures having a second pitch along a second direction that is different from the first direction;
the camera is configured to detect interference patterns of the two additional beams of scattered radiation;
the measurement signal further comprises a signal representation of an additional interferogram based on the interference patterns of the two additional beams of scattered radiation; and
the determining of the deformation is further based on the additional interferogram.

27. A method comprising:
directing two beams of radiation at each target of a plurality of targets disposed on a substrate to produce two beams of scattered radiation from the each target;
detecting interference patterns of the two beams of scattered radiation from the plurality of targets using a camera;
generating a measurement signal comprising a signal representation of an interferogram based on the interference patterns detected by the camera;
adjusting the interference patterns by adjusting a relative phase of the two beams of radiation; analyzing the measurement signal using a controller; and
determining a deformation of the substrate based on the interferogram and the adjusting of the relative phase.

28. The method of clause 27, wherein the adjusting of the interference patterns comprises modulating a phase of at least one of the two beams of radiation using a phase stepper.

29. The method of clause 27, further comprising adjusting the interference patterns by moving the substrate using a substrate table.

30. The method of clause 27, wherein the directing two beams of radiation is performed using a full-field phase coherent illuminator.

31. The method of clause 30, wherein:
the substrate comprises:
   a grid of fields; and
   a scribe lane at an edge of a field;
the plurality of targets are distributed among the field and the scribe lane disposed at the edge of the field; and
the illuminating all targets in the field and the scribe lane disposed at the edge of the field using the full-field phase coherent illuminator and without moving the substrate.

32. The method of clause 27, wherein the detecting comprises detecting at a resolution of at least 100 megapixels.

33. The method of clause 27, wherein the detecting comprises detecting at a resolution of at least 150 megapixels.

34. The method of clause 27, further comprising directing the two beams of scattered radiation from the each target toward the camera using an optical objective having a numerical aperture below 0.5.

35. The method of clause 34, wherein the optical objective comprises a full-field imaging lens having a numerical aperture of less than 0.2 and the directing of the two beams of scattered radiation from the each target toward the camera is performed using the full-field imaging lens.

36. The method of clause 27, wherein the detecting comprises capturing images using the camera at a rate of at least 500 Hz, at least 1 KHz, at least 5 kHz, at least 10 kHz, or at least 100 kHz.

37. The method of clause 27, further comprising compensating for the deformation by adjusting a positioning of a stage or a projection system of a lithographic apparatus.

38. The method of clause 27, comprising compensating for the deformation by modifying a physical characteristic of a patterning device or an alignment of the patterning device of a lithographic apparatus.

The terms “radiation,” “beam,” “light,” “illumination,” or the like can be used herein to refer to one or more types of electromagnetic radiation, for example, ultraviolet (UV) radiation (for example, having a wavelength λ of 365, 248, 193, 157 or 126 nm), extreme ultraviolet (EUV or soft X-ray) radiation (for example, having a wavelength in the range of 5-100 nm such as, for example, 13.5 nm), or hard X-ray working at less than 5 nm, as well as particle beams, such as ion beams or electron beams. Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some aspects, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

Although some aspects of the present disclosure are described in the context of lithographic apparatuses in the manufacture of ICs, it should be understood that lithographic apparatuses described herein can be used in other applications, for example, in the manufacture of integrated optical systems, guidance and detection patterns for magnetic domain memories, flat-panel displays, LCDs, thin-film magnetic heads, etc. Those skilled in the art will appreciate that, in the context of such alternative applications, any use of the terms “wafer” or “die” herein can be considered as specific examples of the more general terms “substrate” or “target portion”, respectively. A substrate can be processed before or after exposure in, for example, a track unit (a tool that typically applies a layer of resist to a substrate and develops the exposed resist) and/or a metrology unit. Where applicable, aspects disclosed herein can be applied to such and other substrate processing tools. Furthermore, a substrate can be processed more than once, for example in order to create a multi-layer IC, so that the term substrate used herein can also refer to a substrate that already contains multiple processed layers.

Furthermore, although some aspects of the present disclosure are described in the context of optical lithography, it should be understood that aspects of the present disclosure are not limited to optical lithography. For example, in imprint lithography, a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present specification is to be interpreted by those skilled in relevant art(s) in light of the teachings herein.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed. The foregoing description of specific aspects will so fully reveal the general nature of the present disclosure that others can, by applying knowledge within the skill of the art, readily modify and/or adapt for various applications such specific aspects, without undue experimentation and without departing from the general concept of the present disclosure. Therefore, such adaptations and modifications are intended to be within the meaning and range of equivalents of the disclosed aspects, based on the teaching and guidance presented herein.

It is to be understood that the Detailed Description section, and not the Summary and Abstract sections, is intended to be used to interpret the claims. The Summary and Abstract sections can set forth one or more, but not necessarily all, aspects of the present disclosure as contemplated by the inventor(s), and thus, are not intended to limit the present disclosure and the appended claims in any way. The breadth and scope of the protected subject matter should not be limited by any of the above-described aspects, but should be defined in accordance with the following claims and their equivalents.

1. A system comprising:
an illuminator configured to direct two beams of radiation at each target of a plurality of targets disposed on a substrate to produce two beams of scattered radiation from the each target;
a camera configured to detect interference patterns of the two beams of scattered radiation from the plurality of targets and to generate a measurement signal comprising a signal representation of an interferogram based on the interference patterns;
a modulator system configured to adjust the interference patterns by adjustment of a relative phase of the two beams of radiation; and
a controller configured to analyze the measurement signal and to determine the deformation of the substrate based on the interferogram and the adjustment of the relative phase.

2. The system of claim 1, wherein the modulator system comprises a phase stepper configured to adjust the interference patterns by modulation of a phase of at least one of the two beams of radiation.

3. The system of claim 1, wherein the substrate is positioned by a substrate table that is configured to move the substrate to adjust the interference patterns detected by the camera.

4. The system of claim 1, wherein the illuminator comprises a full-field phase coherent illuminator.

5. The system of claim 4, wherein:
the substrate comprises:
one or more fields; and
a scribe lane at an edge of a field;
the plurality of targets are distributed among the one or more fields and the scribe lane; and
the full-field phase coherent illuminator is configured to illuminate all targets in the one or more fields and the scribe lane without moving the substrate.

6. The system of claim 1, wherein the camera has a resolution of at least 100 megapixels.

7. The system of claim 1, wherein the camera has a resolution of at least 150 megapixels.

8. The system of claim 1, further comprising an optical objective having a numerical aperture less than 0.5.

9. The system of claim 1, wherein the optical objective comprises a full-field imaging lens having a numerical aperture of less than 0.2.

10. The system of claim 1, wherein the camera is further configured to capture images at a rate of at least 500 Hz.

11. The system of claim 1, wherein the controller is further configured to, or another controller is configured to, compensate for the deformation by adjustment of a positioning of a stage or a projection system of a lithographic apparatus.

12. The system of claim 1, wherein the controller is further configured to, or another controller is configured to, modify a physical characteristic of a patterning device or an alignment of the patterning device of a lithographic apparatus.

13. The system of claim 1, wherein:
the illuminator is further configured to direct two additional beams of radiation at the each target of the plurality of targets to produce two additional beams of scattered radiation, wherein each target comprises a first periodic structure having a first pitch along a first direction and a second periodic structure having a second pitch along a second direction that is different from the first direction;
the camera is configured to detect interference patterns of the two additional beams of scattered radiation;
the measurement signal further comprises a signal representation of an additional interferogram based on the interference patterns of the two additional beams of scattered radiation; and
the controller is configured to determine the deformation is further based on the additional interferogram.

14. A lithographic apparatus comprising:
an illumination system configured to illuminate a pattern of a patterning device;
a projection system configured to project an image of the pattern onto a substrate; and
an inspection system comprising:
an illuminator configured to direct two beams of radiation at each target of a plurality of targets disposed on the substrate to produce two beams of scattered radiation from each target;
a camera configured to detect interference patterns of the two beams of scattered radiation from the plurality of targets and to generate a measurement signal comprising a signal representation of an interferogram based on the interference patterns;
a modulator system configured to adjust the interference patterns by adjustment of a relative phase of the two beams of radiation; and
a controller configured to analyze the measurement signal and to determine deformation of the substrate based on the interferogram and the adjustment of the relative phase.

15. The lithographic apparatus of claim 14, wherein the modulator system comprises a phase stepper configured to adjust the interference patterns by modulation of a phase of at least one of the two beams of radiation.

16. A method comprising:
directing two beams of radiation at each target of a plurality of targets disposed on a substrate to produce two beams of scattered radiation from each target;
detecting interference patterns of the two beams of scattered radiation from the plurality of targets using a camera;
generating a measurement signal comprising a signal representation of an interferogram based on the interference patterns detected by the camera;
adjusting the interference patterns by adjusting a relative phase of the two beams of radiation;
analyzing the measurement signal using a controller; and
determining a deformation of the substrate based on the interferogram and the adjusting of the relative phase.

17. The method of claim 16, wherein the adjusting of the interference patterns comprises modulating a phase of at least one of the two beams of radiation using a phase stepper.

18. The method of claim 16, further comprising adjusting the interference patterns by moving the substrate using a substrate table.

19. The method of claim 16, wherein the directing two beams of radiation is performed using a full-field phase coherent illuminator.

20. The method of claim 16, wherein the detecting comprises detecting at a resolution of at least 100 megapixels.
